(19) United States
(12) Patent Application Publication
(10) Pub. No.: US 2012/0111838 A1
(43) Pub. Date: May 10, 2012

(54) Thermal Processing of Substrates with Pre- and Post-Spike Temperature Contro

(75) Inventors: Arthur W. Zafiropoulo, Atherton, CA (US); Andrew M. Hawryluk, Los Altos, CA (US); James T. McWhirter, San Jose, CA (US); Serguei G. Anikitchev, Belmont, CA (US)

(73) Assignee: Ultratech, Inc., San Jose, CA (US)

(21) Appl. No.: 13/347,618

(22) Filed: Jan. 10, 2012

Related U.S. Application Data
(63) Continuation of application No. 12/287,085, filed on Oct. 6, 2008, now abandoned.

(51) Int. Cl. H01L 21/324; B23K 26/08; B23K 26/12; B23K 26/00

(52) U.S. Cl. 219/121.65; 219/121.76; 219/121.8; 219/121.86; 219/444.1

(57) ABSTRACT

Provided are apparatuses and method for the thermal processing of a substrate surface, e.g., controlled laser thermal annealing (LTA) of substrates. The invention typically involves irradiating the substrate surface with first and second images to process regions of the substrate surface at a substantially uniform peak processing temperature along a scan path. A first image may serve to effect spike annealing of the substrates while another may be used to provide auxiliary heat treatment to the substrates before and/or after the spike annealing. Control over the temperature profile of the prespike and/or postspike may also reduce stresses and strains generated in the wafers. Also provided are microelectronic devices formed using the inventive apparatuses and methods.

### BACKGROUND OF THE INVENTION

1. Field of the Invention

The present invention relates to thermal processing of substrates using a plurality of radiation sources that generate first and second images that optionally overlap. In particular, the invention relates to such processing wherein regions of the substrate surface are each processed at an optionally controlled prespike temperature, followed by a controlled uniform peak temperature, followed by an optionally controlled postspike temperature.

2. Description of Related Art

Fabrication of semiconductor-based microelectronic devices often involves subjecting a semiconductor substrate “thermal processing” to activate dopant atoms implanted in junction regions (e.g., source and drain regions) of the substrate. For example, the source/drain parts of transistors may be formed by exposing regions of a silicon wafer to electrostatically accelerated dopants. After implantation, the dopants are electrically inactive. Activation of these dopants may be achieved by annealing the substrate, i.e., heating the substrate to a particular processing temperature for a period of time sufficient for the crystal lattice to incorporate the dopants in its structure. The required time period depends on the processing temperature. When subjected to an elevated temperature for an extended time period, the dopants tend to diffuse throughout the lattice. As a result, the dopant distribution profile may change from an ideal box shape to a profile having a shallow exponential fall-off.

By employing higher annealing temperatures and shorter annealing times it is possible to reduce dopant diffusion and to retain the dopant distribution profile achieved after implant. For example, thermal processing (TP) encompasses certain techniques for annealing source/drain regions formed in silicon wafers as part of the process for fabricating semiconductor devices such as integrated circuits (ICs). An objective of rapid thermal processing (RTP) is to produce shallow doped regions with very high conductivity by rapidly heating the wafer to temperatures near the semiconductor melting point to incorporate dopants at substitutional lattice sites, and then rapidly cool the wafer to “freeze” the dopants in place.

Laser-based technologies have been employed to carry out TP with time scales much shorter than those employed by conventional RTP systems. Exemplary terminology used to describe laser based TP techniques include laser thermal processing (LTP), laser thermal annealing (LTA), and laser spike annealing (LSA). In some instances, these terms can be used interchangeably. In any case, these techniques typically involve forming a laser beam into a long, thin image, which in turn is scanned across a surface to be heated, e.g., an upper surface of a semiconductor wafer. For example, a 0.1-mm wide beam may be raster scanned over a semiconductor wafer surface at 100 mm/s to produce a dwell time of less than about one millisecond for the heating cycle. A typical maximum temperature during this heating cycle might be 1350° C. Within the dwell time needed to bring the wafer surface up to the maximum temperature, a layer only about 100 to about 200 micrometers below the surface region is heated. Subsequently, the bulk of the millimeter thick wafer serves to cool the surface about as quickly as it was heated once the laser beam is past.

LTP may employ either pulsed or continuous radiation. For example, LTP may use a continuous, high-power, CO₂ laser beam of an infrared wavelength, e.g. λ=10.6 μm which is raster scanned over the wafer surface so all regions of the surface are exposed to at least one pass of the spike heating beam. This wavelength, large relative to the typical dimensions of wafer features, can sometimes be uniformly absorbed as the beam scans across a patterned silicon wafer resulting in each point on the wafer being subject to very nearly the same maximum temperature.

Nevertheless, lightly doped and undoped silicon may not significantly absorb radiation from a CO₂ laser spike annealing beam of 10.6 μm radiation at temperatures significantly below about 400° C. because beam's photon energy is less than the bandgap energy of undoped silicon. Accordingly, U.S. Patent Application No. 20070072400 to Bakeman describes a method of thermally processing a semiconductor substrate having a surface and a semiconductor bandgap energy. The method involves irradiating the substrate with an activating radiation beam having photons with an energy greater than the semiconductor bandgap energy to locally heat the substrate to increase an amount of absorption of an annealing radiation beam. Then, the substrate is irradiated with the annealing radiation having photons which are absorbed by the free carriers to substantially heat the substrate.

Other patents describe techniques in which more than one laser beam may be employed. For example, U.S. Pat. No. 7,148,159 to Talwar et al. describes technology for performing laser thermal annealing (LTA) of a substrate using an annealing radiation beam that is not substantially absorbed in the substrate at room temperature. The technology may involve using a first beam to preheating the substrate to a critical temperature and then irradiating the substrate with annealing radiation to generate a peak temperature capable of annealing the substrate. Typically, a peak temperature is reached in a short amount of time, thereby resulting in a thermal spike. Afterwards, the entire substrate may be cooled down.

Nevertheless, uncontrolled heating and/or cooling may introduce uncontrolled stresses in substrates. Such stresses may result in suboptimal electronic performance when the substrates contain microelectronic devices, e.g., ICs. In extreme cases, uncontrolled stresses may result in catastrophic mechanical failure leading to substrate breakage. Also, simple laser annealing with a single dwell time may not provide optimal electronic performance for the devices. Laser annealing with a short dwell time produces high activation with little or no diffusion. There are some device designs that would benefit from a small amount of diffusion, along with the high activation from the laser annealing. In other device fabrication implementations, a second (lower temperature) anneal for a short period of time may be beneficial to remove defects in the implanted regions of the structure. Both the stress management and the device to performance optimization can be effected with an additional thermal beam.

Thus, there is a need in the art to effect control over pre- and/or post-thermal spike temperatures in thermal processes involving laser annealing and like technologies.

### SUMMARY OF THE INVENTION

In an embodiment, the invention provides an apparatus for thermally processing a surface of a substrate. The apparatus include a stage, a plurality of radiation sources, and a controller operatively coupled to the stage and radiation sources. The stage supports the substrate and places the substrate surface in a radiation-receiving position. The radiation sources form images that optionally overlap on the upper substrate surface. The controller provides relative scanning motion between the substrate surface and the images to allow the images to process regions of the substrate surface along a scan path at a substantially uniform peak processing temperature.

Typically, first and second images are formed by first and second radiation sources, respectively. In addition, the images may have controlled intensity profiles and sizes. The relative scanning motion may be controlled and optionally reversed as well. As a result, the first and second images, in combination, may bring regions of the substrate surface from an initial temperature to a first intermediate temperature, e.g., in a gradual manner, then to the peak processing temperature for a spike processing period and to a second intermediate temperature, e.g., in a spiking manner, followed by cooling to a final temperature, e.g., in a gradual manner, all at controlled rates. In some instance, intermediate temperatures may be independently selected from a range of about 400° C. to about 1000° C. The intermediate temperatures may be approximately equal.

The heating and/or cooling rates may be selected for a variety of purposes, e.g., to reduce stress accumulation in and/or improve electronic performance of the substrate. In some instances, the prespike heating rate may allow regions of the substrate surface to be heated from the initial temperature to the first intermediate temperature in less than about 2 seconds so the temperature increases in a desired manner to form a desired temperature profile. The temperature profile may be linear or nonlinear. Similarly, the postspike cooling rate may be selected in an analogous manner.

The peak temperature may vary. For example, the peak temperature may be less than about 1412° C. for substrates comprising silicon wafers. In addition, the spike processing period may be no more than about 10 milliseconds.

Different radiation sources may be used. Suitable radiation sources include, for example, lasers, laser diodes, heat lamps, of varying wavelengths. Depending on the application, the radiation sources may produce continuous and/or pulsed beams. The beams may be used to produce an elongate image having a lengthwise axis adapted to travel along a scan path that is nonparallel or at least partially perpendicular to the lengthwise axis of the elongate image.

In another embodiment, a method is provided for thermally processing a surface of a substrate. The method involves irradiating the substrate surface with first and second images that optionally overlap, and providing relative scanning motion between the substrate surface and the images to process regions of the substrate surface along a scan path at a substantially uniform peak processing temperature. The first and second images allow, e.g., regions of the substrate surface along the scan path to be: (a) heated from an initial temperature to a first intermediate temperature at a controlled prespike heating rate; (b) brought from the first intermediate temperature to the peak processing temperature to a second intermediate temperature within a spike processing period; and (c) cooled from the second intermediate temperature to a final temperature at a controlled postspike cooling rate.

In still another embodiment, a semiconductor wafer is provided that includes microelectronic devices produced using the method and/or apparatus described above. The wafer may include devices of a lithographic node no greater than about 65 nm.

### BRIEF DESCRIPTION OF THE DRAWINGS

FIG. 1 is a schematic side view of an exemplary embodiment of a thermal processing apparatus according to the present invention.

FIG. 2 is a graph that plots the temperature experienced by a region of a substrate surface over time according to an exemplary process of the invention.

FIG. 3 is a plan view of the substrate surface of FIG. 1 as it is undergoing thermal processing, illustrating an exemplary embodiment of the overlap of the annealing beam image and the auxiliary beam image as formed at the substrate surface.

FIGS. 4A and 4B, collectively referred to as FIG. 4 are plan views similar to FIG. 3, illustrating an exemplary embodiment. In FIG. 4A, the auxiliary beam image generally precedes the annealing beam image so the auxiliary beam only overlaps the leading region of the spike annealing image. In FIG. 4B, the auxiliary beam image generally follows the annealing beam image so the annealing beam image only overlaps the leading region of the auxiliary beam image.

FIG. 5 is a plan view similar to FIG. 3, illustrating an exemplary embodiment where the auxiliary beam image extends forward in the scan direction relative to the annealing beam image and wherein the two images overlap.

FIG. 6 is a plan view similar to FIGS. 3 and 5, illustrating an exemplary embodiment where the auxiliary beam image encompasses the entire annealing beam image.

FIG. 7 shows an auxiliary beam unit that includes a plurality of auxiliary radiation beam generators each feeding an optical fiber.

FIG. 8 schematically depicts use of the auxiliary beam unit of FIG. 7 to illuminate a substrate surface.

FIG. 9 graphically depicts a “snap shot” of the relative intensities of annealing image 150 and auxiliary image 250 on the substrate surface along the Y axis at an arbitrary point in time.

The drawings are intended to illustrate various aspects of the invention, which can be understood and appropriately carried out by those of ordinary skill in the art. The drawings may not be to scale as certain features of the drawings may be exaggerated for emphasis and/or clarity of presentation.

### DETAILED DESCRIPTION OF THE INVENTION

### Definitions and Overview

Before describing the present invention in detail, it is to be understood that this invention, unless otherwise noted, is not limited to specific substrate constructions, substrate materials, radiation sources, as such may vary. It is also to be understood that the terminology used herein is for the purpose of describing particular embodiments only, and is not intended to be limiting.

It must be noted that, as used in this specification and the appended claims, the singular forms “a”, “an” and “the” include both singular and plural referents unless the context clearly dictates otherwise. Thus, for example, reference to “beam” includes a plurality of beams as well as a single beam, reference to “a wavelength” includes a range or plurality of wavelengths as well as a single wavelength, reference to “a region” includes a combination of regions as well as single region, and the like.

In describing and claiming the present invention, the following terminology will be used in accordance with the definitions set out below.

The term “Brewster angle” is used to refer to the angle of minimum or near-minimum reflectivity of P-polarized light from a surface. Strictly speaking, films on the surface of an object, such as a silicon wafer, may prevent the object from having a true Brewster angle, for which the reflectivity is minimized. Accordingly, the Brewster angle as used herein for a specular surface formed from a variety of different films stacked on a substrate can be thought of as an effective Brewster angle, or the angle at which the reflectivity of P-polarized radiation is at a minimum. This minimum angle typically coincides with, or is near, the angle of the true Brewster angle for the substrate.

The term “laser” is used herein in its ordinary sense and refers to a device that emits electromagnetic radiation (light) through a process called stimulated emission. Such radiation is usually but not necessarily spatially coherent. Typically lasers, but not necessarily, emit electromagnetic radiation with a narrow wavelength spectrum (“monochromatic” light). The term laser is to be interpreted broadly unless its usage clearly indicates otherwise, and the interpretation may encompass, for example, gas laser, e.g., CO₂ lasers, and laser diodes.

The term “lithographic node” refers a set of industry standards relating to line spacing and other geometric considerations associated with mass manufacture of semiconductor-based integrated circuitry in a repetitive array. In general, smaller nodes correspond to smaller line widths and greater device density.

The terms “optional” and “optionally” are used in their ordinary sense and mean that the subsequently described circumstance may or may not occur, thus the description includes instances when the circumstance occurs and instances when it does not.

The term “semiconductor” is used to refer to any of various solid substances having electrical conductivity greater than insulators but less than good conductors, and that may be used as a base material for computer chips and other electronic devices. Semiconductors are comprised substantially of a single element, e.g., silicon or germanium, or may be comprised of compounds such as silicon carbide, aluminum phosphide, gallium arsenide, and indium antimonide. Unless otherwise noted, the term “semiconductor” includes any one or a combination of elemental and compound semiconductors, as well as strained semiconductors, e.g., semiconductors under tension and/or compression. Exemplary indirect bandgap semiconductors suitable for use with the invention include Si, Ge, and SiC. Direct bandgap semiconductors suitable for use with the invention include, for example, GaAs, GaN, and InP.

The terms “substantial” and “substantially” are used in their ordinary sense and refer to matters that are considerable in importance, value, degree, amount, extent or the like. For example, the phrase “substantially uniform peak processing temperature” refers to a peak processing temperature that lies within a range of no more than a few degrees so any variations in a peak processing temperature is negligible in effect when viewed in light of the invention. Other uses of the term “substantially” involve an analogous definition.

The term “substrate” as used herein refers to any material having a surface, which is intended for processing, e.g., a supporting material on which a circuit may be formed or fabricated. The substrate may be constructed in any of a number of forms, for example, such as a semiconductor wafer containing an array of chips, etc., and may be of one or more nonsemiconductor materials as well as one or more semiconductor materials.

As a related matter, the term “wafer” as used herein refers generally to a thin slice of semiconductor used as a base material on which single transistors or integrated-circuit components are formed. The terms “wafer” and “substrate” may be interchangeably used herein unless the context clearly indicates to the contrary.

The present invention generally relates to the thermal processing of a substrate surface, e.g., controlled laser thermal annealing (LTA) of substrates. The invention typically involves irradiating the substrate surface with first and second images to process regions of the substrate surface at a substantially uniform peak processing temperature along a scan path. This is typically achieved by using a stage to support the substrate, first and second radiation sources to form first and second images, respectively, on the upper substrate surface, and a controller operably coupled to the stage and radiation sources to provide relative scanning motion that is optionally reversible between substrate surface and the images that corresponds to the scan path.

The radiation sources typically produce different types of images. At least one radiation source is typically used to produce an image that may serve to effect spike annealing of the substrates. Another may be used to provide auxiliary heat treatment to the substrates before and/or after the spike annealing.

Typically, the first and second images overlap. In such a case, the first image may have an intensity profile and size effective to heat regions of the substrate surface along the scan path preceding the second image from an initial temperature to a first intermediate temperature at a controlled prespike heating rate and/or cool regions of the substrate surface along the scan path following the second image from a second intermediate temperature to a final temperature at a controlled postspike cooling rate. The second image may have an intensity profile and size effective to bring regions of the substrate surface along the scan path from the first intermediate temperature to the peak processing temperature to the second intermediate temperature within a spike processing period. Control over the prespike and/or postspike temperature profile may also reduce stresses and strains generated in the wafers and/or improve device performance.

It is not necessary for annealing and auxiliary images to overlap. In the case where there is sufficient absorption of a spike annealing beam need for preheating, the annealing and auxiliary beams may be used to form separate annealing and auxiliary images. This allows for independent control over the thermal characteristics of the beams as well as the thermal effects of the corresponding images. That is, a second (spike) annealing beam may be used to bring the wafer temperature to its peak temperature, whereas a first (non-spike) beam can bring the wafer to its intermediate temperature for a different (typically, longer) time period.

Exemplary Apparatus

In an apparatus embodiment, the invention provides an apparatus for thermally processing a surface of a substrate. The apparatus include a stage, a plurality of radiation sources, and a controller operatively coupled to the stage and radiation sources. The stage supports the substrate and places the substrate surface in a radiation-receiving position. The radiation sources form overlapping images on the upper substrate surface. The controller provides relative scanning motion between substrate surface and the overlapping images to allow the images to process regions of the substrate surface along a scan path at a substantially uniform peak processing temperature. First and second, e.g., spike annealing and auxiliary images, are formed by first and second radiation sources, respectively. In addition, the images may have controlled intensity profiles and sizes. The relative scanning motion may be controlled as well. As a result, the first and second images, in combination, may bring regions of the substrate surface from an initial temperature to a first intermediate temperature, e.g., in a gradual manner, then to the peak processing temperature in a spike processing period and to a second intermediate temperature, e.g., in a spiking manner, followed by cooling to a final temperature, e.g., in a gradual manner, all at controlled rates.

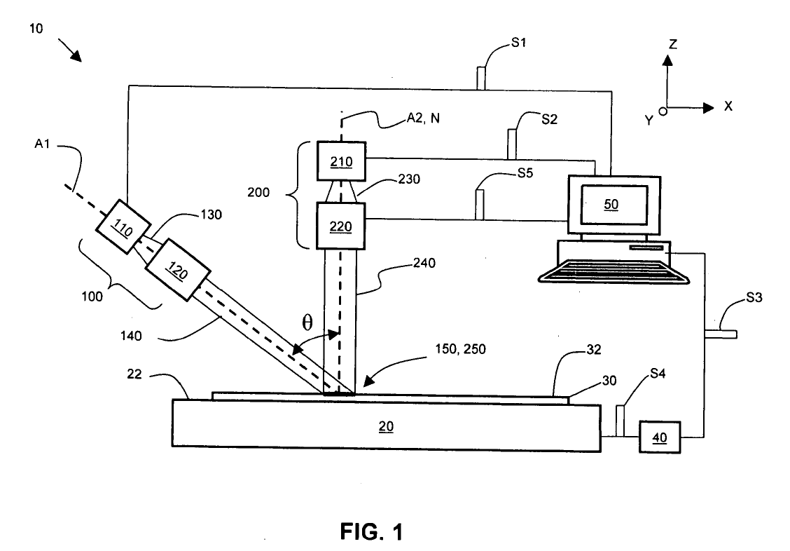

FIG. 1 is a schematic diagram of an exemplary embodiment of a thermal processing apparatus 10 according to the present invention that may be used to anneal and/or otherwise thermally process one or more selected surface regions of a substrate. LTP system 10 includes a movable substrate stage 20 having an upper surface 22 that supports a semiconductor substrate 30 having an upper surface 32. In an exemplary embodiment, semiconductor substrate 30 is of the type that does not efficiently absorb infrared (IR) spike heating beam radiation. However, the semiconductor substrate may in some instances, readily absorb radiation of other wavelengths. The substrate may optionally rest on a heating and/or cooling chuck to provide a constant background temperature. The chuck may exhibit a temperature of about −20° C. to 600° C.

Substrate stage 20 is operably coupled to a stage driver 40, which in turn is operably coupled to controller 50. Substrate stage 20 is adapted to move in the X-Y plane (as well as along the Z-axis) under the operation of controller 50 and stage driver 40 so the substrate can be scanned relative to first and second beams, as discussed below.

LTP system 10 further includes a spike annealing beam unit 100, which in an exemplary embodiment includes, in order along an axis Al, a spike annealing radiation source 110 operably coupled to controller 50, and a spike annealing optical system 120. In an exemplary embodiment, the spike annealing radiation source 110 is a CO₂ laser that emits radiation at a wavelength λ_{H}˜10.6 micrometers. However, the spike annealing radiation source may employ LED or laser diode radiation as well. For example, an array of LED or laser diodes may be used, potentially combined with fiber optics. LED and laser diode technologies are described in greater detail below. In any case, spike annealing radiation source 110 emits radiation 130 that is received by spike annealing optical system 120, which in turn forms a spike annealing beam 140. Spike annealing beam 140 travels along optical axis Al, which makes an angle θ with a substrate surface normal N.

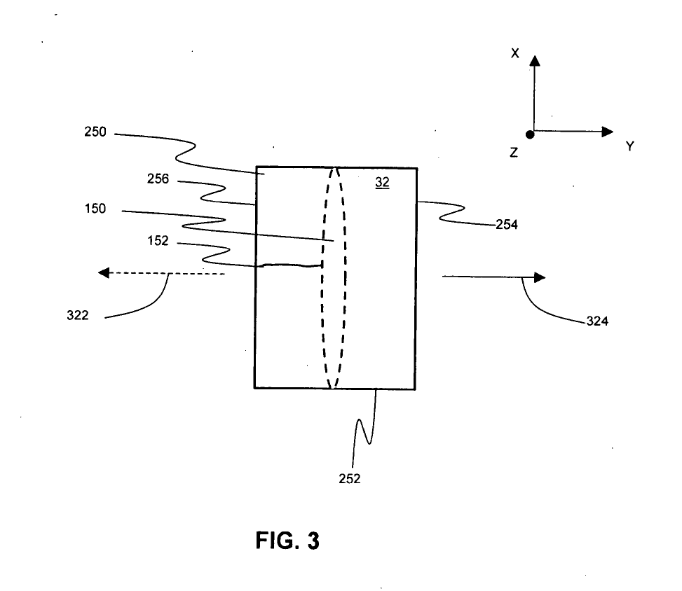

Spike annealing beam 140 forms an image 150 (hereinafter, the “annealing beam image”) at substrate surface 32. In an exemplary embodiment, image 150 is an elongate image, e.g. as a line image, suitable for scanning over the substrate surface to perform thermal processing. Annealing beam image 150 is bounded by an outer edge 152 (e.g., as shown in FIGS. 3-6). To a first approximation, the temperature at substrate surface 32 is proportional to the integral of beam intensity under the annealing beam image profile in the scan direction. This integral changes along the length of the line image, so at some point along the length the temperature falls below a desired temperature for processing the substrate, e.g., a threshold temperature for annealing.

Thus, there are boundaries along the line image, which define the extent of the line image where useful thermal processing occurs. The boundaries are where adjacent scans are butted together. In an exemplary embodiment, the auxiliary beam illuminates a surface region that extends over the spike annealing beam end boundaries on either side of the narrow annealing beam image. As a result, where the spike annealing beam intensity is 5% or greater, it is efficiently absorbed near the substrate surface. This assures that nearly all of the spike annealing beam energy is efficiently utilized.

Apparatus 10 also includes an auxiliary beam unit 200, which in an exemplary embodiment includes, in order along an axis A2, a auxiliary radiation source 210 operably coupled to controller 50, and a auxiliary optical system 220. In an exemplary embodiment, auxiliary radiation source 210 emits radiation that allows for auxiliary heat treatment before and/or after the spike annealing of semiconductor substrate 30. Auxiliary radiation source 210 emits radiation 230, which is received by auxiliary optical system 220, which in turn forms a auxiliary beam 240. Auxiliary beam 240 travels along optical axis A2 and forms an image 250 (hereinafter, the “auxiliary beam image”) at substrate surface 32. Auxiliary beam image 250 has an outer edge 252 (FIGS. 3-6) that, in an exemplary embodiment, may be defined by a threshold intensity value. The outer edge 252 includes a leading edge 254 and a trailing edge 256 (FIG. 3).

The auxiliary radiation source 210 may take a number of different forms. In some instances, a single laser diode may be used. Alternatively, the invention may employ a plurality of emitters, e.g., LEDs or laser diodes. Such emitters may be arranged in a pattern, an array, or other convenient arrangement. In some instances, the source may take the form of a bar, a stack, or fiber coupled modules. For example, the source may include a semiconductor laser bar emitting radiation in the 800-830 nm spectral range. An example of such a diode bar is available from Spectra-Physics, Inc., Tucson Ariz. A bar of about 1cm in length is capable of emitting 90 Watts of continuous power. At this wavelength, the absorption length in undoped crystalline silicon is about 10 microns, which is about the depth required to effectively absorb the longer wavelength spike annealing beam 140.

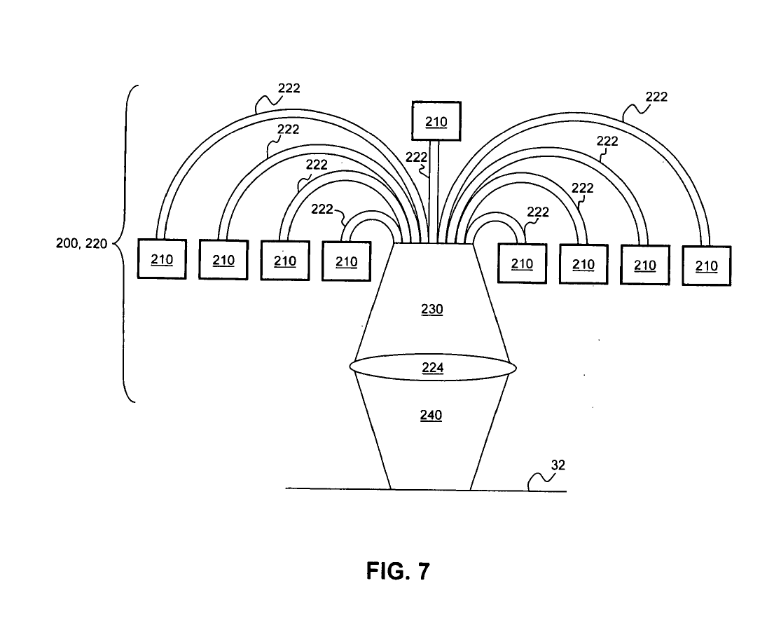

Fiber optic technologies may be used as well. For example, as shown in FIG. 7, a auxiliary beam unit 200 may include, a plurality of auxiliary radiation beam generators 210 in the form of photodiodes or laser diodes, each feeding a fiber 222 of the auxiliary optical system 220. The fibers 222 may be arranged to form a close-pack linear array. Each generator 210 emits radiation 230, which is received by auxiliary optical system 220, which in turn forms a auxiliary beam 240. A lens 224 may be provided to focus the beam before it reaches the substrate surface 32. In some idealized instances, the substrate surface 32 represents an imaged plane formed by the lens 224. The fiber array may be imaged on the substrate so that each fiber is mainly responsible for providing illumination along a small section, also some overlap may be provided between adjacent fibers to achieve good uniformity. As discussed below, the generators for each section may be independently modulated to produce an arbitrary or predetermined illumination profile on the wafer.

Returning to FIG. 1, although the axis of the auxiliary beam and the substrate normal are shown coincident, it is often not desirable to image a radiation beam laser on a substrate at normal incidence. When a laser is used for example, any reflected light may cause instabilities when it returns to the laser cavity. Accordingly, the apparatus depicted in FIG. 1 may be modified with optical axis A2 placed at an angle relative to surface normal N (i.e., at non-normal incidence) so auxiliary radiation that reflects from substrate surface 32 does not return to auxiliary radiation source 210 or spike annealing radiation source 110. As discussed below in detail, another reason for providing optical axis A2 at an incident angle, other than at normal incidence, is that efficiently coupling of auxiliary beam 240 into the substrate may best be accomplished by judicious choice of incident angle and polarization direction, e.g., making the incident angle equal to the Brewster angle for the substrate and using p-polarized radiation.

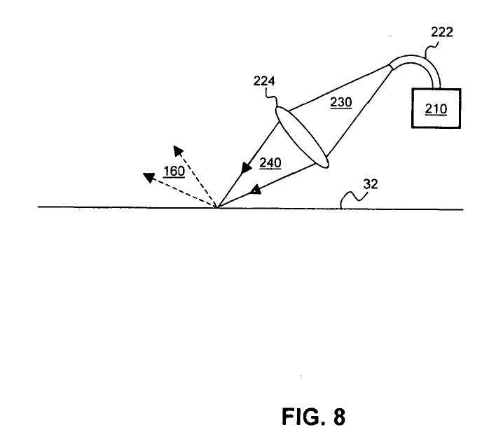

In any case, fiber optic technologies may be advantageously used to ensure proper spatial relationship between components of the invention. For example, FIG. 8 schematically depicts how the auxiliary beam unit 200 of FIG. 7 may be rearranged to avoid placing the generators 210 in the path of specularly reflected radiation 160 from the substrate. As discussed below, additional optical equipment such as telecentric relay systems may be used with fiber optic or waveguide technologies. Other uses of fiber optic technologies in conjunction with the invention will become apparent to one of ordinary skill in the art upon routine experimentation.

### Exemplary Method

Before describing methods of the invention in detail, some historical perspective is in order. Currently, a number of laser thermal processing techniques, e.g., spike annealing techniques, require that a continuous CO₂ laser beam be shaped into a beam that strikes the substrate at or near Brewster's angle (˜75° incidence). The image formed by such a beam may be about 0.1 mm wide and about 10 mm long. The beam is scanned over the substrate in a direction perpendicular to its long direction and the integrated dose during scanning must be uniform to about 1% over the 10 mm length of the beam.

To carry out such laser thermal processing techniques, a substrate may be uniformly preheated in its entirety, e.g., by a heated chuck or by heating lamps, to an desired intermediate temperature (typically between 400° C. and 700° C.) prior to the formation of a spike annealing image. The substrate may be preheated to the intermediate temperature in about one to tens of seconds. Once the intermediate temperature is reached, it is maintained for a period of time (e.g., from a second to tens of seconds to perhaps even a hundred seconds). Thermal spike annealing typically occurs within a short period of time (generally lasting a fraction of a millisecond to a few milliseconds) as the beam is scanned over the substrate. Because the CO₂ laser beam strikes the substrate at the intermediate temperature, the beam is readily absorbed. Then, the entire substrate is cooled down slowly. The cool down generally takes several tens of seconds and is uncontrolled as the substrate heat radiates to its surrounding area.

In contrast, the invention involves the use of an auxiliary radiation source to control the preheat and the post-spike cool down in addition to or as a replacement to the heated chuck or lamps described above. The entire substrate may begin at room temperature or at an elevated temperature. The auxiliary radiation source may be used to illuminate and preheat a large area to a desired temperature. However, the ramp up rate and/or the ramp duration and the preheat temperature may be controlled by the intensity profile of the image formed by radiation from the auxiliary radiation source. Similarly, the intensity profile of the image formed from the auxiliary radiation source may be used to control the ramp down rate and the ramp down duration. The bulk of the substrate remains at room temperature or the original elevated temperature, and which assists in controlling the ramp down rate.

In short, one of the many embodiments of the invention provides a method for thermally processing a surface of a substrate. The method involves irradiating the substrate surface with first and second overlapping images whereby the substrate may be at room temperature or at an elevated temperature, and providing relative scanning motion between the substrate surface and the overlapping images to process regions of the substrate surface along a scan path at a substantially uniform peak processing temperature. The first and second images may allow, e.g., regions of the substrate surface along the scan path to be: (a) heated from an initial temperature to a first intermediate temperature at a controlled prespike heating rate; (b) brought from the first intermediate temperature to the peak processing temperature to a second intermediate temperature within a spike processing period; and (c) cooled from the second intermediate temperature to a final temperature at a controlled postspike cooling rate. Optionally, either step (a) or step (b) may be omitted, or can be used separately without the spike anneal.

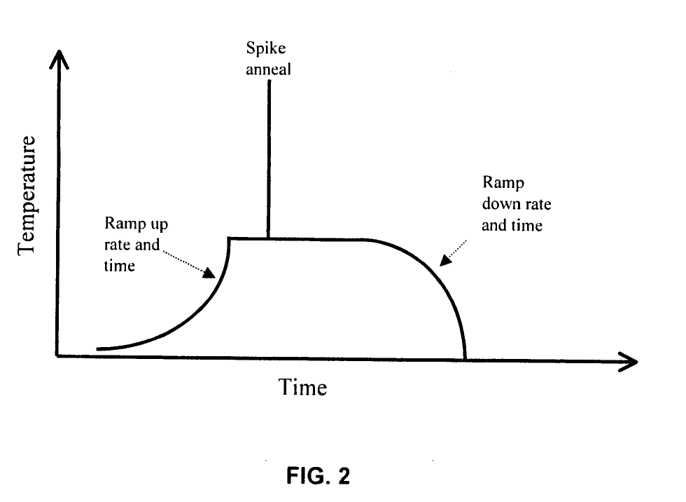

To improve spike annealing processes, the invention may use an auxiliary laser and suitable optics: (1) to control the preheat temperature profile experienced by a substrate before (and/or after) spike annealing is carried out and/or (2) to regulate the temperature profile experienced by a substrate during post-spike cool down or after the spike anneal. FIG. 2 shows a plot of the temperature that may be experienced by a particular region of a substrate surface processed according to an embodiment of the invention. As shown, the particular region begins at room temperature, although the region may begin at some elevated temperature. The auxiliary laser may illuminate an extended area and be used to scan over and preheat the particular region to a desired intermediate plateau temperature. Once the region reaches the desired intermediate plateau temperature, an annealing laser image may be scanned over the region to effect spike annealing thereof. During spike annealing, the temperature of the region illuminated by the annealing laser image may shoot up to a desire peak processing temperature. Once the annealing laser image has passed, the particular region's temperature may plummet down to the intermediate plateau temperature and controllably ramped down to the original temperature, e.g., room temperature, the original elevated temperature or the chuck temperature over time.

In the aforementioned exemplary scenario, both the ramp up rate, the ramp duration and the preheat temperature may be controlled by the illumination profile of the image auxiliary the laser used to preheat the wafer. Similarly, the illumination profile of the image from the same laser may be used to control the ramp down rate and the ramp down duration.

The above exemplary scenario may be carried out using the apparatus shown in FIG. 1. Controller 50 may send a control signal S1 to spike annealing radiation source 110 to actuate the annealing radiation source. In response thereto, spike annealing radiation source 110 emits radiation 130 that is received by LTP optical system 120, which forms spike annealing beam 140. Spike annealing beam 140 then proceeds along axis Al to substrate surface 32, where it forms a annealing beam image 150.

Controller 50 also sends a control signal S2 to auxiliary radiation source 210 to actuate the auxiliary radiation source. In response thereto, auxiliary radiation source 210 emits radiation 230 that is received by auxiliary optical system 220, which forms auxiliary beam 240. Auxiliary beam 240 then proceeds along axis A2 to substrate surface 32, where it forms an auxiliary beam image 250.

FIG. 3 is a close-up plan view of substrate surface 32 illustrating an exemplary embodiment of the relative positions of annealing beam image 150 and auxiliary beam image 250 for the above described scenario. As shown, annealing beam image 150 may fit within auxiliary beam image 250, although the image edge may not be rigorously defined in either case. As shown, the annealing beam image 150 is centered between the leading edge 254 and trailing edge 256 of auxiliary beam image 250.

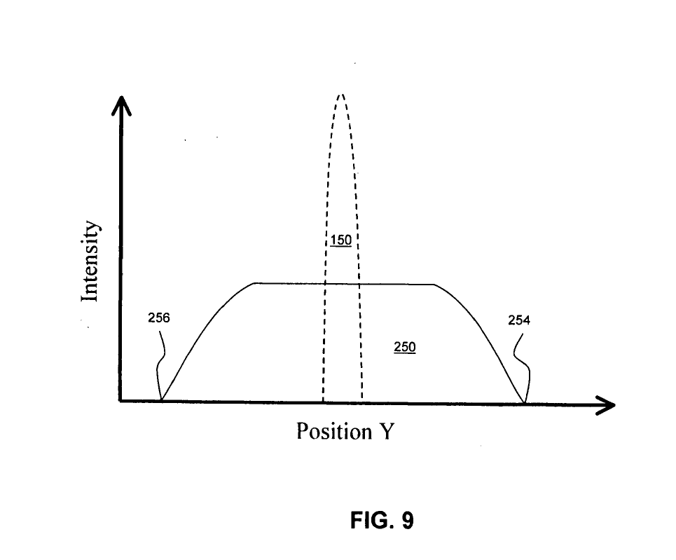

Auxiliary beam image 250 may, as shown in FIG. 2, at least partially overlaps with annealing beam image 150. However, image overlap is not a requirement of the invention, particularly when a heated chuck is used. FIG. 9 is a graph that provides a “snap shot” of the relative intensities of annealing image 150 and auxiliary image 250 along the Y axis at a particular point in time. As shown, image 150, whose intensity profile is shown in a dotted curve, exhibits a higher peak intensity than image 250, whose intensity profile is shown in a solid curve.

Controller 50 also actuates stage driver 40 via a control signal S3. Stage driver 40, in turns, sends a drive signal S4 to stage 20 that causes the stage to move in the negative Y-direction, as indicated by arrow 322 in FIG. 3, so annealing beam image 150 and auxiliary beam image 250 are scanned over substrate surface 20 in the positive Y direction (i.e., the scan direction), as indicated by arrow 324. As a result, the particular regions of the substrate surface processed by scanning images 150 and 250 may experience the temperature profile shown in FIG. 2.

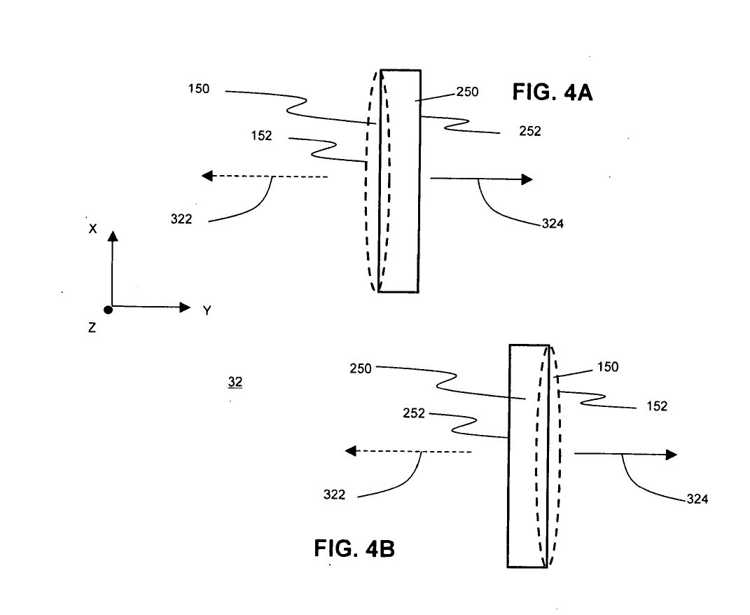

In another exemplary embodiment illustrated in FIG. 4, auxiliary beam image 250 immediately may either precede or follow annealing beam image 150. The positions, sizes and amount of overlap of the heating and auxiliary beam images (or the lack of overlap) depends on the desired effects of thermal processing. For some device optimization, it may be necessary for the auxiliary beam to following the annealing beam, and for other devices, the opposite may be true. It is not necessary for the two beams to overlap if a heated chuck is used to raise the temperature of the substrate sufficiently high so the annealing beam is readily absorbed.

For example, as shown in FIG. 4A, the invention may be used to control the preheat temperature profile experienced by a substrate before spike annealing is carried out without regulating the temperature profile experienced by a substrate during post-spike cool down. In such a case, the auxiliary beam image 250 could overlap only the leading portion of the annealing beam image 150. Similarly, as shown in FIG. 4B, the invention may be used to control the post spike temperature profile experienced by a substrate after spike annealing is carried out without preheating the substrate for spike annealing. In such a case, the leading portion auxiliary beam image 250 could overlap only the trailing portion of the annealing beam image 150.

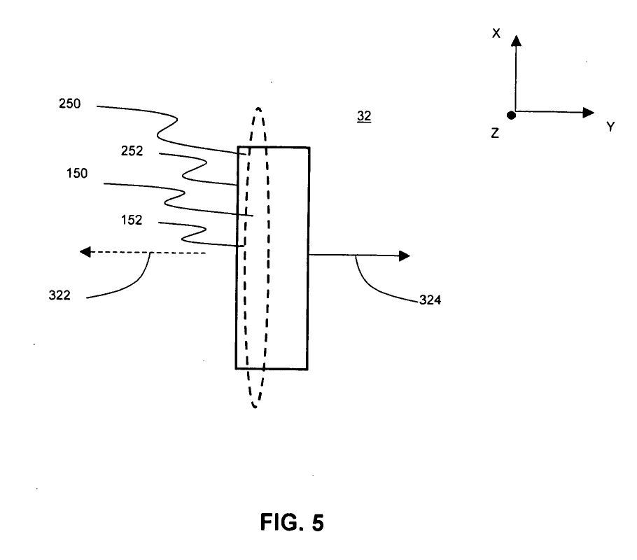

Another exemplary embodiment of an image geometry is illustrated in FIG. 5, wherein auxiliary beam image 250 is formed so it extends forward of annealing beam image 150 in a scan direction 324. This allows for a longer period of preheat than post spike time for the preheating.

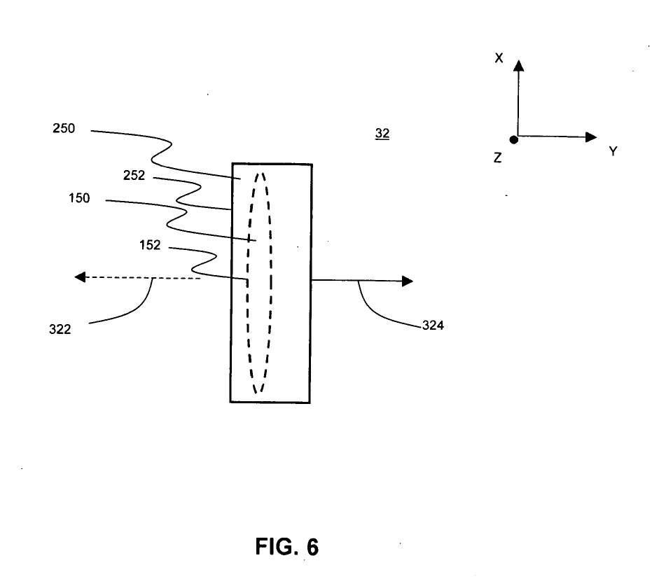

Another exemplary embodiment of an image geometry is illustrated in FIG. 6, auxiliary beam image 250 is larger than annealing beam image along the X and Y directions.

In sum, the invention may be advantageously used to effect localized thermal processing by controlling both the local temperature and the local temperature-temporal slope depending on image intensity profiles, image geometries, scan velocities, and etc.

### Inventive Variations

Variations of the present invention will be apparent to those of ordinary skill in the art. For example, while the drawings generally depict annealing and auxiliary images that overlap, the invention does not require such images to overlap. In addition, upon routine experimentation, one may find that optimal first and second intermediate temperatures are each about 400° C. to about 1000° C. The intermediate temperature may be equal or different.

When the invention employs preheating, the controlled prespike heating rate may be selected to reduce stress accumulation in and/or improve electronic performance of the substrate. For example, the controlled prespike heating rate may allow regions of the substrate surface along the scan path preceding the second image to be heated from the initial temperature to the first intermediate temperature in less than about 2 seconds. In addition or in the alternative, the controlled prespike heating rate may allow regions of the substrate surface along the scan path preceding the second image to be heated from the initial temperature to the first intermediate temperature along a desired temperature profile.

Similarly, when the invention employs controlled postspike cooling techiques, the controlled postspike cooling rate is selected to reduce stress accumulation in and/or improve electronic performance of the substrate. In some instances, the controlled postspike cooling rate allows regions of the substrate surface along the scan path following the second image to be cooled from the second intermediate temperature to the final temperature in less than about 2 seconds. In addition or in the alternative, the controlled postspike cooling rate may allow regions of the substrate surface along the scan path following the second image to cool from the second intermediate temperature to the final temperature along a desired temperature profile.

For silicon substrates, the peak temperature may be less than about 1412° C., depending on whether a melt or submelt annealing processes is desired. In any case the spike processing period may be no more than about 10 millisecond regardless of the any preheating or post-spike cooling.

Different radiation sources may be used. Radiation sources may be independently selected from, however they are not limited to, lasers and laser diodes that may produce continuous beam. Typically, the annealing image is an elongate image having a lengthwise axis and the scan path is perpendicular to the lengthwise axis of the elongate image. In any case, the relative positions of first and second images as well as the sequence in which they proceed along the scan path may be switchable, e.g., by changing the direction of travel for the stage.

Due to the unprecedented control over temperature experienced by substrates produced using the invention, it is believed that any semiconductor wafer processed using the invention will exhibit microstructural and/or electronic performance advantages over those using processes known in the art. Such advantages may be measured via known techniques such as stress mapping and metrological techniques, e.g., described in U.S. Patent Application Publication No. 20070212856 to Owen. Thus, the invention also provides wafers that include microelectronic devices produced using the inventive method, e.g., microelectronic devices of a lithographic node no greater and/or less than about 65 nm, as well as the microelectronic devices themselves. Thus, microelectronic devices produced using the inventive methods of lithographic nodes of no greater about 45 nm, 32 nm, 16 nm and/or 11 nm also represent novel and nonobvious improvements over the art.

In addition, it is to be understood that, while the invention has been described in conjunction with the preferred specific embodiments thereof, the foregoing description is intended to illustrate and not limit the scope of the invention. Other aspects, advantages, and modifications within the scope of the invention will be apparent to those skilled in the art to which the invention pertains.

All patents and patent applications mentioned herein are hereby incorporated by reference in their entireties to an extent not inconsistent with the above description.

1. An apparatus for thermally processing a surface of a substrate, comprising:
a stage adapted to support the substrate and place the substrate surface in a radiation-receiving position;
first and second radiation sources adapted to form first and second images, respectively, on the upper substrate surface; and
a controller operably coupled to the stage and radiation sources, the controller adapted to provide relative scanning motion between substrate surface and the images so as allow the images to process regions of the substrate surface along a scan path at a substantially uniform peak spike processing temperature,
wherein:
the first image has an intensity profile and size effective to:
heat regions of the substrate surface along the scan path from an initial temperature at a controlled heating rate, and/or controlled heating duration, and
cool regions of the substrate surface along the scan path to a final temperature at a controlled cooling rate and/or controlled cooling duration, and
the second image has an intensity profile and size effective to bring regions of the substrate surface along the scan path from the an intermediate temperature higher than the initial temperature to the peak spike processing temperature to an intermediate temperature higher than the final temperature.

2. The apparatus of claim 1, further comprising a chuck for bringing the substrate to the initial temperature.

3. The apparatus of claim 1, further comprising a chuck for bringing the substrate to the final temperature.

4. The apparatus of claim 1, wherein the first and second radiation sources are adapted to form overlapping first and second images.

5. The apparatus of claim 1, wherein the first and second radiation sources are adapted for form nonoverlapping first and second images.

6. The apparatus of claim 1, wherein the intermediate temperatures are each about 400° C. to about 1000° C.

7. The apparatus of claim 1, wherein the intermediate temperatures are approximately equal.

8. The apparatus of claim 1, wherein the controlled prespike heating rate, the heating controlled duration or the first intermediate temperature is selected to reduce stress accumulation in and/or improve electronic performance of the substrate.

9. The apparatus of claim 8, wherein the controlled prespike heating rate allows regions of the substrate surface along the scan path preceding the second image to be heated from the initial temperature to the first intermediate temperature in less than about 2 seconds.

10. The apparatus of claim 8, wherein the controlled prespike heating rate allows regions of the substrate surface along the scan path preceding the second image to be heated from the initial temperature to the first intermediate temperature along a desired temperature profile.

11. The apparatus of claim 1, wherein the controlled postspike cooling rate is selected to reduce stress accumulation in and/or improve electronic performance of the substrate.

12. The apparatus of claim 11, wherein the controlled postspike cooling rate allows regions of the substrate surface along the scan path following the second image to be cooled from the second intermediate temperature to the final temperature in less than about 2 seconds.

13. The apparatus of claim 9, wherein the controlled postspike cooling rate allows regions of the substrate surface along the scan path following the second image to cool from the second intermediate temperature to the final temperature along a desired temperature profile.

14. The apparatus of claim 1, wherein the peak temperature is less than about 1412° C.

15. The apparatus of claim 1, wherein the spike processing period is no more than about 10 millisecond.

16. The apparatus of claim 1, wherein the substrate comprises silicon.

17. The apparatus of claim 1, wherein at least one of the first and second radiation sources includes a laser and/or laser diode.

18. The apparatus of claim 17, wherein the laser and/or laser diode is adapted to produce a continuous beam.

19. The apparatus of claim 1, wherein the second image is an elongate image having a lengthwise axis.

20. The apparatus of claim 19, wherein the scan path is perpendicular to the lengthwise axis of the elongate image.

21-26. (canceled)

27. An apparatus for thermally processing a surface of a substrate, comprising:
a stage adapted to support the substrate and place the substrate surface in a radiation-receiving position;
first and second radiation sources adapted to form first and second images, respectively, on the upper substrate surface; and
a controller operably coupled to the stage and radiation sources, the controller adapted to provide relative scanning motion between substrate surface and the images so as allow the images to process regions of the substrate surface along a reversible scan path at a substantially uniform peak processing temperature, wherein:
the first image has an intensity profile and size effective to:
heat regions of the substrate surface along the scan path preceding, during or following the second image from an initial temperature to a first intermediate temperature at a controlled heating rate, and/or;
cool regions of the substrate surface along the scan path preceding, during or following the second image from a second intermediate temperature to a final temperature at a controlled cooling rate, and
the second image has an intensity profile and size effective to bring regions of the substrate surface along the scan path to the peak processing.

28. The apparatus of claim 27, wherein:
the first image has an intensity profile and size effective to heat regions of the substrate surface along the scan path preceding the second image from an initial temperature to the first intermediate temperature at a controlled heating rate, and
the second image has an intensity profile and size effective to bring regions of the substrate surface along the scan path from the first intermediate temperature to the peak processing temperature within a spike processing period.

29. The apparatus of claim 27, wherein:
the first image has an intensity profile and size effective to cool regions of the substrate surface along the scan path following the second image from the second intermediate temperature to a final temperature at the controlled cooling rate, and
the second image has an intensity profile and size effective to bring regions of the substrate surface along the scan path to the peak processing temperature to the second intermediate temperature within a spike processing period.

30. The apparatus of claim 27, wherein the first image provides no control over controlled prespike heating rate.

31-33. (canceled)
